(19) United States
(12) Patent Application Publication
(10) Pub. No.: US 2013/0082310 A1
(43) Pub. Date: Apr. 4, 2013

(54) Semiconductor Structure and Method for Manufacturing the Same

(71) Applicants: Haizhou Yin, Poughkeepsie, NY (US); Huilong Zhu, Poughkeepsie, NY (US); Zhijiong Luo, Poughkeepsie, NY (US)

(72) Inventors: Haizhou Yin, Poughkeepsie, NY (US); Huilong Zhu, Poughkeepsie, NY (US); Zhijiong Luo, Poughkeepsie, NY (US)

(21) Appl. No.: 13/580,964

(22) PCT Filed: May 14, 2012
(86) PCT No.: PCT/CN12/00648

§ 371 Date: Aug. 24, 2012

(30) Foreign Application Priority Data
Sep. 30, 2011 (CN) 201110298318.9
May 14, 2012 (CN) PCT/CN2012/000648

(51) Int. Cl. H01L 21/336; H01L 29/78

(52) U.S. Cl. 257/288; 438/197; 257/E29.255; 257/E21.409

(57) ABSTRACT

The invention provides a semiconductor structure, comprising a substrate, a semiconductor fin, a gate stack, source/drain regions and a semiconductor body, wherein: the semiconductor fin is located on the semiconductor body, and is connected with the semiconductor body, and both ends of the semiconductor body are connected with the substrate; the gate stack covers the central portion of the semiconductor fin, and extends to the surface of the substrate; and the source/drain regions are located at the end portions of the semiconductor fin; and wherein, cavities are formed in the substrate at both sides of the semiconductor fin, and an insulating material is filled into the cavities. Correspondingly, the invention further provides a method for manufacturing a semiconductor structure. By isolating the semiconductor body under the semiconductor fin from the substrate under the semiconductor body, not only the substrate region under the semiconductor fin is effectively reduced, but also the leakage current between the semiconductor device and the substrate is reduced, and the performance of the semiconductor device is improved.

### CROSS REFERENCE

This application is a National Phase application of, and claims priority to, PCT Application No. PCT/CN2012/000648, filed on May 14, 2012, entitled ‘SEMICONDUCTOR STRUCTURE AND METHOD FOR MANUFACTURING THE SAME’, which claimed priority to Chinese Application No. CN 201110298318.9, filed on Sep. 30, 2011. Both the PCT Application and Chinese Application are incorporated herein by reference in their entireties.

### FIELD OF THE INVENTION

The present invention relates to the semiconductor technical field, more particularly, to a semiconductor structure and a method for manufacturing the same.

### BACKGROUND OF THE INVENTION

In the semiconductor technology, the focus of research is shifted to a three-dimensional (3D) device structure, in order to realize a full-depletion type device. Three-dimensional type device structure indicates forming a FinFET on a substrate, comprising forming a channel region in the middle of a semiconductor fin, forming a gate on the sidewalls of the semiconductor fin, and forming source/drain regions at both ends of the semiconductor fin.

In the three-dimensional semiconductor device structure, since the channel region is not comprised in the bulk silicon or SOI any more, instead, it is independent of these structures, a full-depletion type channel having an extremely thin thickness may be made by means of etching and so on.

However, in the three-dimensional semiconductor device structure, although the thickness of the semiconductor fin (fin-type channel) made by means of etching and so on may be very thin, there is still bulk silicon under the fin-type channel. Since in the three-dimensional semiconductor device structure, the channel is formed mainly using the independent semiconductor fin and the semiconductor device is formed on the sidewalls of the semiconductor fin, the bulk silicon existing under the semiconductor fin will lead to existence of leakage current between the semiconductor device (source/drain regions) and the substrate. Eliminating the leakage current between the semiconductor device and the substrate is an urgent problem to be solved.

### SUMMARY OF THE INVENTION

In order to reduce the leakage current between the semiconductor device and the substrate, the invention provides a semiconductor structure and a method for manufacturing the same.

The invention provides a semiconductor structure, comprising: a substrate, a semiconductor fin, a gate stack, source/drain regions and a semiconductor body, wherein

the semiconductor fin is located on the semiconductor body, and is connected with the semiconductor body, and both ends of the semiconductor body are connected with the substrate;
the gate stack covers the central portion of the semiconductor fin, and extends to the surface of the substrate; and
the source/drain regions are located at the end portions of the semiconductor fin; and
wherein cavities are formed in the substrate at both sides of the semiconductor fin, and an insulating material is filled into the cavities.

Correspondingly, the invention further provides a method for manufacturing a semiconductor structure, comprising:

a) providing a substrate, forming a semiconductor fin on the substrate, and forming a spacer on the sidewalls of the semiconductor fin;
b) etching the substrate at both sides of the semiconductor fin to form cavities, wherein, the portion of the substrate connected with the semiconductor fin and located above the cavities is a semiconductor body;
c) filling an insulating material into the cavities; and
d) forming a gate stack and source/drain regions.

Compared to the prior art, the technical solution provided by the invention has the following advantages.

By firstly implementing dry etching and then implementing anisotropic wet etching to the substrate at both sides of the semiconductor fin to form cavities which are connected, and filling an insulating material into the cavities, the substrate region under the semiconductor fin (i.e. semiconductor body) is effectively reduced, further the leakage current between the semiconductor device and the substrate is reduced, and the performance of the semiconductor device is improved.

### BRIEF DESCRIPTION OF THE DRAWINGS

Other features, purposes and advantages of the present invention will become more apparent by reading the detailed descriptions of the non-limiting embodiments made with reference to the drawings below, wherein:

FIG. 1 is a flow chart showing a method for manufacturing the semiconductor structure in accordance with the present invention; and

FIGS. 2-11 are diagrammatic cross-sections of the stages for manufacturing the semiconductor structure according to the flow chart shown in FIG. 1 in accordance with a preferred embodiment of the present invention.

Wherein identical or similar reference signs indicate identical or similar components in the drawings.

### DETAILED DESCRIPTION OF THE EMBODIMENTS

In order to make the objects, technical solutions and advantages of the present invention to be clearer, the embodiments of the present invention will be described in detail with reference to the drawings below.

The embodiments of the present invention are described in detail below, and the examples of the embodiments are provided in the drawings, wherein identical or similar reference signs indicate identical or similar components or components having identical or similar functions throughout the drawings. The embodiments described below with reference to the drawings are illustrative, which are used to explain the present invention, but can not be construed as limit of the present invention.

The disclosure herein provides many different embodiments or examples for realizing different structures of the present invention. In order to simplify the disclosure of the present invention, components and settings of specific examples are described below. Of course, they are only examples and are not intended to limit the present invention. Furthermore, reference numbers and/or letters may be repeated in different examples of the present invention. Such repetitions are for simplification and clearness, which per se do not indicate the relations of the discussed embodiments and/or settings. Moreover, the present invention provides examples of various specific processes and materials, but the applicability of other processes and/or application of other materials may be appreciated by those having ordinary skill in the art. Besides, the following described structure where a first feature is “on/above” a second feature may either comprise the embodiment where the first feature and the second feature are directly contacted, or may comprise the embodiment where additional features are formed between the first feature and the second feature, and thus the first feature and the second feature may not be directly contacted. The mutual relationships of various structures described in the invention include certain extensions made in accordance with requirements of the process or manufacturing procedure, e.g., the term “vertical” means the difference between an angle between two planes and 90° is within a tolerance allowed by the process or manufacturing procedure.

The invention provides a semiconductor structure, as shown in FIG. 11, the semiconductor structure comprises: a substrate 100, a semiconductor fin 200, a gate stack, source/drain regions and a semiconductor body 120, wherein: the semiconductor fin 200 is located on the semiconductor body 120, and is connected with the semiconductor body 120; both ends of the semiconductor body 120 are connected with the substrate 100. Since the semiconductor body 120 is formed by etching the substrate 100, the semiconductor body 120 is of the same material as the substrate 100, it preferably is monocrystalline Si, and also may be one of monocrystalline Ge and monocrystalline SiGe, or any combination thereof in other embodiments. Wherein, cavities 400 are formed in the substrate 100 located at both sides of the semiconductor fin 200, into which an insulating material 500 is filled, the insulating material 500 preferably is one of SiO₂ and SiN, or the combination thereof. Preferably, there is a dielectric film 130 on the surface of the semiconductor body 120. The thickness of the dielectric film 130 is 7 nm-10 nm, it can further ensure the isolation of the semiconductor body 120 from the substrate 100 located under the semiconductor body 120. The dielectric film 130 may be an oxide film, a nitride film, an oxynitride film or other thin films that may implement the insulating function. In the embodiments of the invention, the dielectric film 130 preferably is an oxide film.

The gate stack covers the central portion of the semiconductor fin 200, and extends to the surface of the substrate 100, wherein the gate stack comprises a gate dielectric layer 270 and a gate 260 located on the gate dielectric layer 270, the material of the gate dielectric layer 270 may be silicon oxide, silicon nitride, or the combination thereof, and also may be a high K gate dielectric, for example, one of HfO2, HfSiO, HfSiON, HfTaO, HfTiO, HfZrO, Al2O3, La2O3, ZrO2 and LaAlO, or any combinations thereof, the thickness of the gate dielectric layer 270 may be about 2 nm-3 nm, e.g., 2.5 nm, the material of the gate 260 may be a metal material, the thickness thereof may be about 50 nm-100 nm, e.g., 60 nm, 70 nm, 80 nm or 90 nm. The source/drain regions are located on both end portions of the semiconductor fin 200 that are not covered by the gate stack.

In the semiconductor structure provided by the invention, the substrate region connected with the semiconductor fin 200, that is, the semiconductor body 120, is connected with the substrate 100 on both ends, and there is an insulating material 500 beneath and at both sides of the semiconductor body 120 and above the substrate 100, such that the substrate region under the semiconductor fin is effectively reduced, further the leakage current between the semiconductor device and the substrate is reduced, the performance of the semiconductor device is improved.

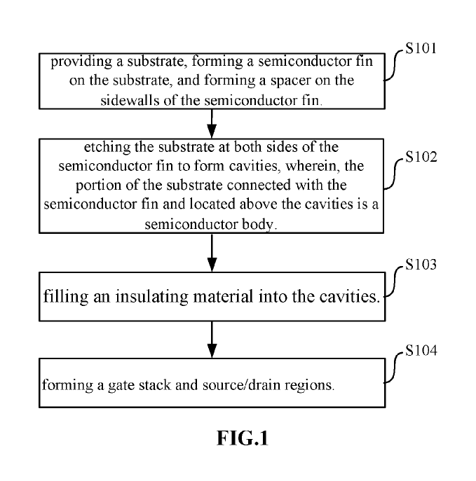

The invention further provides a manufacturing method for a semiconductor structure, in the following text, the manufacturing method in FIG. 1 will be illustrated in combination with FIGS. 2-9.

Firstly, in step S101, a substrate 100 is provided, a semiconductor fin 200 is formed on the substrate 100, and a spacer 220 is formed on sidewalls of the semiconductor fin 200.

Specifically, as shown in FIG. 2, firstly a substrate 100 is provided. The substrate 100 preferably is a silicon substrate, the substrate 100 also may be other semiconductor materials, for example, one of monocrystalline Ge and monocrystalline SiGe, or any combination thereof. A mask layer 110 is formed on the substrate 100, the material thereof may be SiN.

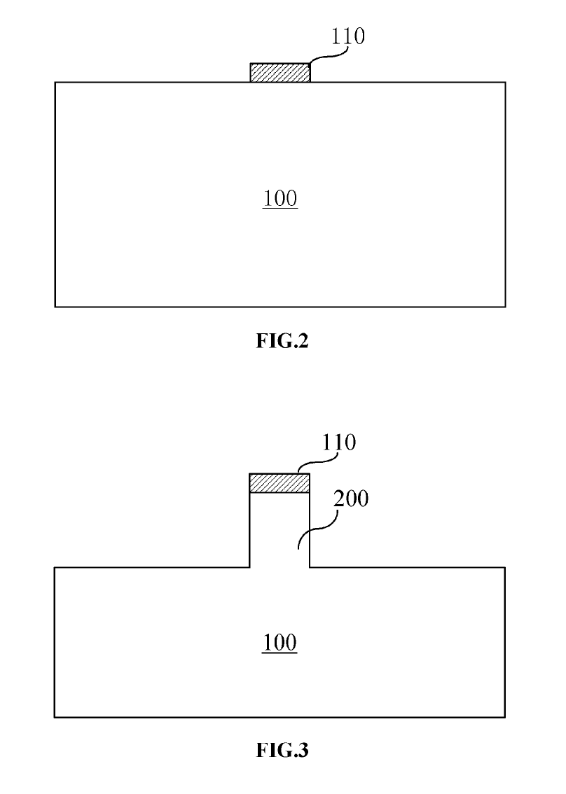

As shown in FIG. 3, the substrate 100 is etched with the mask layer 110 as a mask, forming a semiconductor fin 200.

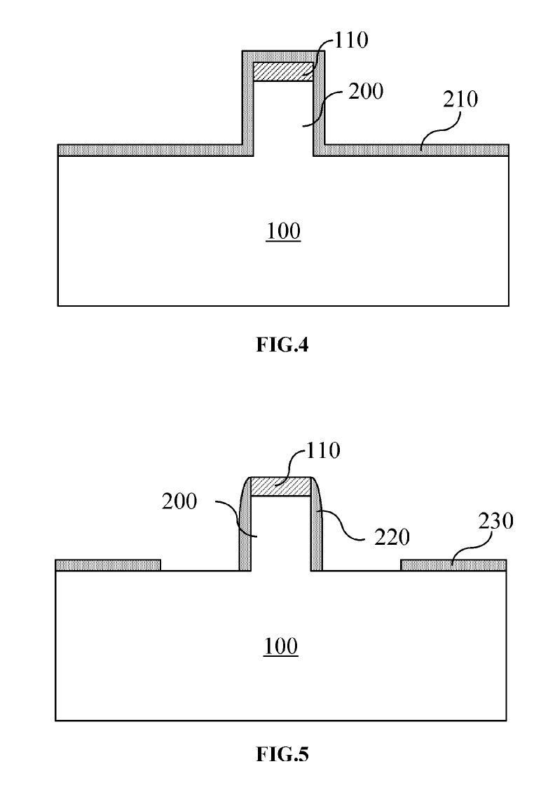

Thereafter, as shown in FIGS. 4 and 5, a mask layer 210 is deposited, covering the substrate 100 and the semiconductor fin 200, the material of the mask layer 210 may be SiN; next, the mask layer 210 is covered with a layer of photoresist, and openings are formed on the photoresist by exposure and development, the openings being located at both sides of the semiconductor fin 200; then, the mask layer 210 is etched, removing the mask layer 210 in the openings to form the spacer 220 that surrounds the semiconductor fin 200 and masks 230; lastly, the remaining photoresist is removed.

Then, step S102 is performed, wherein the substrate 100 at both sides of the semiconductor fin 200 is etched to form cavities, wherein, the portion of the substrate 100 connected with the semiconductor fin 200 and located above the cavities is a semiconductor body 120.

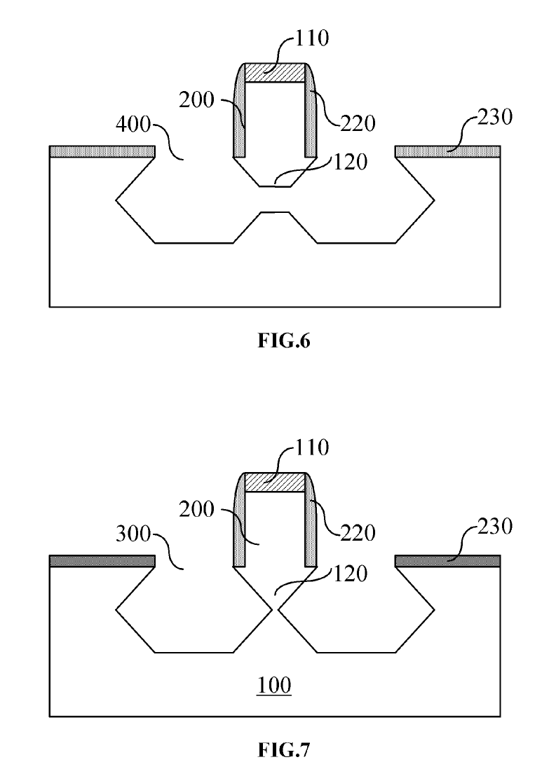

Specifically, as shown in FIG. 6, with the spacer 220 and the masks 230 as a mask, firstly the substrate 100 is etched by dry etching, forming grooves 300 in the substrate 100 at both sides of the semiconductor fin 200; then, the grooves 300 are etched by wet etching, such that the grooves 300 at both sides of the semiconductor fin 200 are connected to form cavities 400. Wherein, the portion of the substrate 100 located above the cavities 400 and connected with the semiconductor fin 200 is the semiconductor body 120. The dry etching comprises one of plasma etching and reactive ion etching, or any combination thereof, the etching solution used in the wet etching comprises one of potassium hydroxide, tetramethylammonium hydroxide and Ethylenediamine-Catechol, or any combinations thereof.

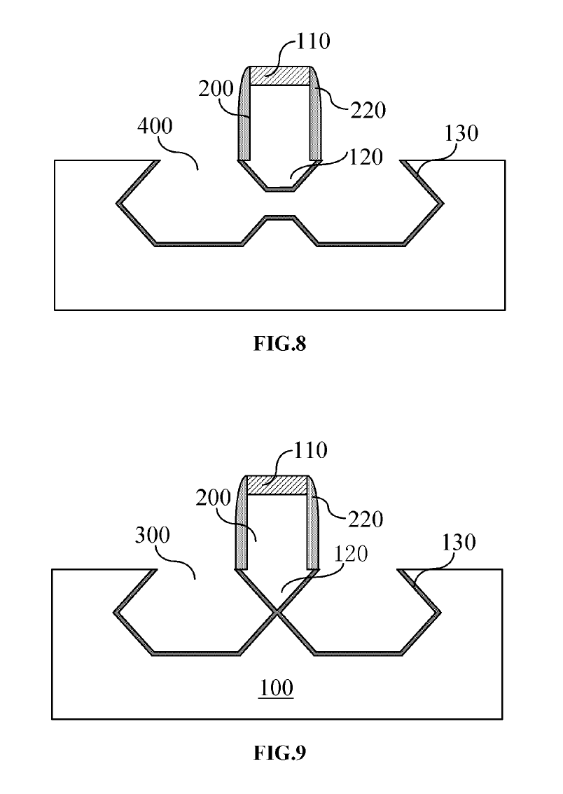

In other embodiments, there is another condition, that is, when the grooves 300 are etched by wet etching, the substrate 100 between the grooves 300 is not completely penetrated through, such that the semiconductor body 120 is still connected with the substrate 100 under it through a small amount of semiconductor material, as shown in FIG. 7. Thus, in this embodiment, the formed cavities 400 are separated. Hence, in order to ensure that the semiconductor body 120 may be separated from the substrate 100 under it, preferably, as shown in FIGS. 8 and 9, a dielectric film 130 is formed on the surface of the semiconductor body 120 after the wet etching, the thickness of the dielectric film 130 is 7 nm-10 nm. The dielectric film 130 may be an oxide film, a nitride film, an oxynitride film or other thin films that may implement the insulating function. In the embodiment of the invention, the dielectric film 130 preferably is an oxide film. Wherein, the semiconductor body 120 may be thermal oxidized to thereby form an oxide film on the surface thereof. The formation method is not limited to the thermal oxidation method, further, the plasma oxidation and the oxidation method of using a high-temperature perchloric acid solution and etc. may be employed. In the condition of forming cavities 400 by wet etching, the oxide film may further isolate the semiconductor body 120 from the substrate 100 under it; in the condition where the wet etching does not completely penetrate through the substrate 100 between the grooves 300, the semiconductor material between the semiconductor body 120 and the substrate 100 which connects them may form an oxide film under the effect of the thermal oxidation, thus the purpose of isolating the semiconductor body 120 from the substrate 100 located under it also may be achieved.

After the semiconductor body 120 is isolated from the substrate 100 located under it, the leakage current between the semiconductor fin 120 and the substrate 100 may be effectively reduced.

Next, step S103 is performed, wherein an insulating material 500 is filled into the cavities.

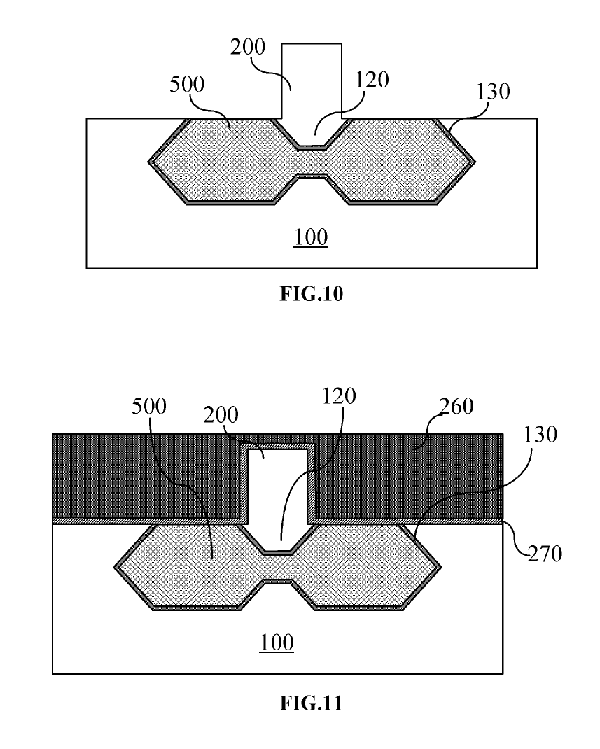

Specifically, as shown in FIG. 10, the cavities 400 are filled with an insulating material 500, and planarization is performed to flush the upper surface of the insulating material 500 with the upper surface of the substrate 100 (in the document, the term “flush” indicates that the difference in height between the two is within a range allowed by process error). Wherein, the insulating material 500 preferably is one of SiO₂ and SiN, or the combination thereof. Optionally, the spacer 220 is removed after planarizing the insulating material 500.

Lastly, in step S104, a gate stack and source/drain regions are formed.

Specifically, as shown in FIG. 11, a gate dielectric material layer (not shown) is formed on the semiconductor fin 200 and the substrate 100, a gate material layer (not shown) is formed on the gate dielectric material layer, and a hard mask material layer (not shown) is formed on the gate material layer, wherein, the gate dielectric material layer may be silicon oxide, silicon nitride, or combination thereof, and also may be a high K gate dielectric, for example, one of HfO2, HfSiO, HfSiON, HfTaO, HfTiO, HfZrO, Al2O3, La2O3, ZrO2 and LaAlO, or any combinations thereof, the thickness of the gate dielectric material layer may be about 2 nm-3 nm, e.g., 2.5 nm. A gate material layer is stacked on the gate dielectric layer, the material of the gate material layer may be a metal material. The thickness of the gate material layer may be about 50 nm-100 nm, e.g., 60 nm, 70 nm, 80 nm or 90 nm. The hard mask material layer may be one of silicon nitride and silicon dioxide, or any combination thereof, and also may be other appropriate materials.

Next, the hard mask material layer, gate material layer and gate dielectric material layer are etched to expose the end portions of the semiconductor fin 200, forming a gate stack. Specifically, the hard mask material layer is patterned, and then the hard mask material layer, gate material layer and gate dielectric material layer are etched using the method such as dry etching and/or wet etching, with the substrate 100 as an etch stop layer, to expose the substrate 100 and two end portions of the semiconductor fin 200, whereby forming a gate stack made up of a gate dielectric layer 270, a gate 260 and a hard mask (not shown), wherein, the gate stack covers the central portion of the semiconductor fin 200, and extends to the surface of the substrate 100 in the direction perpendicular to the semiconductor fin 200, the end portions of the semiconductor fin 200 are located at both sides of the gate stack.

After forming the gate stack, the end portions of the semiconductor fin 200 at both sides of the gate stack are doped, wherein P-type or N-type dopant or impurity are implanted to form source/drain regions (not shown). For a PMOS, the source/drain regions are P-doped; for a NMOS, the source/drain regions are N-doped.

In other embodiments, the gate stack also may be formed after forming the source/drain regions, the process is known by those having ordinary skill in the art, and here we will not go further on this.

By firstly implementing dry etching and then implementing anisotropic wet etching to the substrate 100 at both sides of the semiconductor fin 200 to form cavities 400 which are connected, and filling the insulating material 500 into the cavities 400, the region of the substrate 100 under the semiconductor fin 200 (i.e. semiconductor body) is effectively reduced, further the leakage current between the semiconductor device and the substrate 100 is reduced, the performance of the semiconductor device is improved. Preferably, a dielectric film 130 may be formed on the surface of the semiconductor body 120, such that the semiconductor body 120 is insulated and isolated from the substrate 100 located under it, thus the performance of the semiconductor device is further improved.

Although the illustrative embodiments and their advantages have been described in detail, it shall be appreciated that various changes, substitutions and modifications can be made to these embodiments without departing from the spirit of the invention and the scope defined by the attached claims. As for other examples, it may be appreciated by those having ordinary skill in the art that the sequence of the process steps may be changed while keeping the protection scope of the present invention.

In addition, the present invention is applied to a scope that shall not be limited by the processes, mechanisms, manufacture, material constitutions, measures, methods and steps described in the specific embodiments of the Specification. From the disclosure of the present invention, it may be appreciated by those having ordinary skill in the art that for the processes, mechanisms, manufacture, material constitutions, measures, methods or steps currently existed or will be developed, where they perform substantially the same functions or achieve substantially the same effects as the corresponding embodiments of the present invention, they can be applied in accordance with the present invention. Therefore, the appended claims of the present invention aim to comprise these processes, mechanisms, manufacture, material constitutions, measures, methods or steps within their protection scopes.

1. A semiconductor structure, comprising a substrate (100), a semiconductor fin (200), a gate stack, source/drain regions and a semiconductor body (120), wherein
the semiconductor fin (200) is located on the semiconductor body (120), and is connected with the semiconductor body (120), and both ends of the semiconductor body (120) are connected with the substrate (100);
the gate stack covers the central portion of the semiconductor fin (200), and extends to the surface of the substrate (100);
the source/drain regions are located at the end portions of the semiconductor fin (200); and wherein, cavities (400) are formed in the substrate (100) at both sides of the semiconductor fin (200), and an insulating material (500) is filled into the cavities (400).

2. The semiconductor structure according to claim 1, wherein the semiconductor body (120) is made of one of monocrystalline Si, monocrystalline Ge and monocrystalline SiGe, or any combination thereof.

3. The semiconductor structure according to claim 1, wherein a dielectric film (130) is formed on the surface of the semiconductor body (120).

4. The semiconductor structure according to claim 3, wherein the dielectric film (130) is an oxide film.

5. The semiconductor structure according to one of claim 1, wherein the cavities (400) formed in the substrate (100) at both sides of the semiconductor fin (200) are connected.

6. A method for manufacturing a semiconductor structure, comprising:
a) providing a substrate (100), forming a semiconductor fin (200) on the substrate (100), and forming a spacer (220) on the sidewalls of the semiconductor fin (200);
b) etching the substrate (100) at both sides of the semiconductor fin (200) to form cavities (400), wherein the portion of the substrate (100) connected with the semiconductor fin (200) and located above the cavities (400) is a semiconductor body (120);
c) filling an insulating material (500) into the cavities (400); and
d) forming a gate stack and source/drain regions.

7. The method according to claim 6, wherein
the semiconductor body (120) is made of one of monocrystalline Si, monocrystalline Ge and monocrystalline SiGe, or any combination thereof.

8. The method according to claim 6, wherein after the step b), the method further comprises:
e) forming a dielectric film (130) on the surface of the semiconductor body (120) and the surface of the cavities (400).

9. The method according to claim 8, wherein the dielectric film (130) is an oxide film.

10. The method according to claim 6, wherein the step b) comprises:
etching the substrate (100) by dry etching to form grooves (300) in the substrate (100) at both sides of the semiconductor fin (200); and
etching the grooves (300) by wet etching to form cavities (400).

11. The method according to claim 10, wherein, the step of wet etching the grooves (300) comprises:
etching the grooves (300) by wet etching to make the grooves (300) be connected.

12. The method according to claim 10, wherein the step of forming grooves (300) comprises:
forming a mask layer (210) on the substrate (100) and the semiconductor fin (200);
covering the mask layer (210) with a layer of photoresist, and forming openings on the photoresist by exposure and development, the openings being located at both sides of the semiconductor fin (200);
etching the mask layer (210) in the openings, and removing the photoresist; and
etching the substrate (100) by dry etching in the openings to form grooves (300).

13. The method according to claim 10, wherein
the step of dry etching uses one of plasma etching and reactive ion etching, or any combination thereof.

14. The method according to claim 10, wherein
etching the grooves by wet etching by one of potassium hydroxide, tetramethylammonium hydroxide and Ethylenediamine-Catechol, or any combinations thereof.

15. The method according to claim 6, wherein the step d) comprises:
forming a gate dielectric material layer on the semiconductor fin (200) and the substrate (100),
forming a gate material layer on the gate dielectric material layer, and forming a hard mask material layer on the gate material layer;
etching the hard mask material layer, the gate material layer and the gate dielectric material layer to expose end portions of the semiconductor fin (200) and form a gate stack; and
performing ion implantation to the exposed end portions of the semiconductor fin (200), to form source/drain regions.

16. The semiconductor structure according to claim 3, wherein, the dielectric film (130) is further formed on the surface of the cavities (400).
